(19) United States
(12) Patent Application Publication
(10) Pub. No.: US 2019/0027192 A1
(43) Pub. Date: Jan. 24, 2019

(54) SUPPORT DEVICES FOR DRIVE CARRIER ELECTROMAGNETIC INTERFERENCE SHIELDS

(71) Applicant: HEWLETT PACKARD ENTERPRISE DEVELOPMENT LP, Houston, TX (US)

(72) Inventors: Herbert J. Tanzer, Woodland Park, CO (US); Khosrow Zardkoohi, Fremont, CA (US); Reino E. Hautala, Palo Alto, CA (US)

(21) Appl. No.: 16/070,900

(22) PCT Filed: Jan. 19, 2016
(86) PCT No.: PCT/US2016/013862

§ 371 Date: Jul. 18, 2018

(51) Int. Cl. G11B 33/14; G11B 33/12; H05K 9/00

(52) U.S. Cl. CPC G11B 33/1493; H05K 9/0016; G11B 33/124

(57) ABSTRACT

Example support devices for an electromagnetic interference shield of a drive carrier are disclosed. For example, a support device may include a first bar to extend parallel to a length of a bezel of the drive carrier and a second bar parallel to the first bar, the first bar and the second bar to support spring fingers of the electromagnetic interference shield, the spring fingers comprised of a conductive material, the spring fingers oriented in parallel to one another and perpendicular to the length of the bezel of the drive carrier. The support device may further include a plurality of support ribs perpendicular to and between the first bar and the second bar, the plurality of support ribs to maintain the first bar and the second bar in contact with the spring fingers and to maintain a spring tension in the spring fingers.

### BACKGROUND

A storage chassis may accommodate a plurality of drive assemblies. Each of the plurality of drive assemblies may comprise a drive such as a hard disk drive (HDD) disposed within a drive carrier. The drive carrier may lock and hold the drive in a particular position within the storage chassis. The drive carrier may also protect the drive from electromagnetic interference (EMI) which may be caused by neighboring drives and prevent EMI from the drive from interfering with the neighboring drives.

### BRIEF DESCRIPTION OF THE DRAWINGS

FIG. 1 illustrates an isometric view of an example drive carrier, including an example electromagnetic interference shield and an example support device;

FIG. 2 illustrates an additional isometric view of an example drive carrier, including an example electromagnetic interference shield and an example support device; and

FIG. 3 illustrates a front view of an example drive carrier chassis, including at least one drive carrier with an example electromagnetic interference shield and an example support device.

### DETAILED DESCRIPTION

In one example, a support device for an electromagnetic interference shield of a drive carrier is disclosed. For example, the support device may include a first bar to extend parallel to a length of a bezel of the drive carrier, a second bar parallel to the first bar, the first bar and the second bar to support spring fingers of the electromagnetic interference shield, the spring fingers comprised of a conductive material, the spring fingers oriented in parallel to one another and perpendicular to a length of the bezel of the drive carrier. The support device may further include a plurality of support ribs perpendicular to and between the first bar and the second bar, the plurality of support ribs to maintain the first bar and the second bar in contact with the spring fingers and to maintain a spring tension in the spring fingers.

In another example, an electromagnetic interference system for a drive carrier is described. In one example, the electromagnetic interference system may include an electromagnetic interference shield and a support device. The electromagnetic interference shield may include a panel and spring fingers attached to the panel, the spring fingers comprised of a conductive material, the spring fingers oriented in parallel to one another and perpendicular to a length of a bezel of the drive carrier. The support device may include a first bar to extend parallel to a length of the bezel of the drive carrier, a second bar parallel to the first bar, the first bar and the second bar to support the spring fingers of the electromagnetic interference shield, and a plurality of support ribs perpendicular to and between the first bar and the second bar, the plurality of support ribs to maintain the first bar and the second bar in contact with the spring fingers and to maintain a spring tension in the spring fingers.

In another example, a drive carrier for a drive chassis is described. For instance, the drive carrier may include a housing to fit in a slot of the drive chassis, an electromagnetic interference shield, and a support device. The electromagnetic interference shield may be affixed to the housing and may include a plurality of spring fingers. The support device may include a first bar to extend parallel to a length of a bezel of the drive carrier, a second bar parallel to the first bar, the first bar and the second bar to support the spring fingers of the electromagnetic interference shield, and a plurality of support ribs perpendicular to and between the first bar and the second bar, the plurality of support ribs to maintain the first bar and the second bar in contact with the spring fingers and to maintain a spring tension in the spring fingers.

A storage enclosure, such as a drive cage or a blade enclosure, may include disks and drives, such as hard disk drive (HDD) or solid state drive (SSD) storage devices, mounted in drive carriers in various configurations, such as “just a bunch of disks” (JBODs), flashBODs, a redundant array of independent disks (RAID), and so forth. As referred to herein, any of such storage enclosures may be referred to as a chassis. The drive carriers provide a number of features including handling and hot swap-ability, shock and vibration protection, rotational vibration interference (RVI) control, air flow paths for cooling, electromagnetic interference (EMI) emissions attenuations, and electrical grounding control. In one example, a drive carrier may include an EMI shield to fit securely around a carrier module, or housing, of the drive carrier. The EMI shield may be deployed at the drive carrier-to-chassis interface, and may impact the various drive carrier features mentioned above. In one example, the EMI shield may include a plurality of spaced-apart spring fingers along a top and bottom, and two sides of a panel having various air inlet holes. The spring fingers may contact with spring fingers of another EMI shield of an adjacent drive carrier in an adjacent slot/bay of the chassis, or may contact with a metallic wall of the chassis or cage. For instance, there may be a sequence of spring fingers contacting one another from one drive carrier to the next in a “drive bank,” until spring fingers of an EMI shield of a last drive carrier in the drive bank touch a metallic wall of the chassis. In addition, the chassis may be grounded to a rack, and so on.

The latest high power drives may output up to 25 watts or more, which may call for various cooling solutions. In accordance with the present disclosure, the slot pitch (e.g., the spacing between bays and/or the width of each bay) may be increased from standard slot/bay sizes. This may provide improved cooling of the drives in the chassis through increased airflow around the sides of the drives from a front to a rear of the chassis. For instance, drives, drive carriers, and EMI shields may be designed and optimized for use in 2.5 inch bays, 3.5 inch bays, or 5.25 inch bays (where, the inch size is in reference to the historical disk size used in the bay, and is not necessarily representative of the actual bay cross-sectional dimensions). The slot pitch, or bay size, may therefore be increased with respect to such customary dimensions. However, with an increased slot pitch, the spring fingers of the EMI shields from one drive carrier to the next may not provide a sufficient spring tension for proper EMI grounding. For instance, the spring fingers may be designed to provide a particular spring tension force when compressed between spring fingers of an adjacent EMI shield and/or a wall of chassis. However, since the spring fingers may need to bridge a wider gap as compared to the slot pitch for which the EMI shields were originally intended, the spring fingers may fail to provide the same spring tensions when deployed in a larger slot, or may completely fail to make contact.

In one example, the present disclosure provides a support device for an EMI shield of a drive carrier. The support device may increase the stiffness of the springs of the EMI shield, and thereby increase the contact pressure and provide improved EMI grounding. For example, the support device may sit between two rows of the spring fingers and exert an outward force on the spring fingers such that a separation distance between spring fingers in the first and second rows is increased, e.g., when the spring fingers are not compressed by external forces of a chassis wall or spring fingers of an EMI shield of an adjacent drive carrier. In one example, the support device may be fabricated from a same material as the EMI shield, e.g., a conductive metal. In another example, the support device may comprise a different material, such as a plastic, a carbon fiber, and so forth. With the support device deployed between the two rows of spring fingers, the spring tension of the spring fingers when installed in a bay with increased slot pitch may be the same or close to the spring tension that is provided by the spring fingers when installed in a conventional slot for which the EMI shield was designed and in the absence of the support device.

As mentioned above, a purpose of the EMI shield may be to attenuate EMI emissions that may be generated by the drive or by other components within the chassis. To maintain an effective EMI seal, the aperture or gap spacing between spring fingers may be tightly controlled to have a “characteristic length” that is uniform to with a certain precision. With next generation high-speed interface devices, e.g., 24 Gb/s Serial Attached Small Component Serial Interface (SCSI)/(SAS), 25 Gb/s Ethernet, and 32 Gb/s Fibre Channel (FC), as well as other components within an enclosure, additional high frequency EMI may be generated.

In one example, a support device of the present disclosure may provide for attenuation of additional high frequency EMI as compared to the attenuation capabilities of the EMI shield alone. In one example, the attenuation of high frequency EMI is provided via a plurality of metallic tabs of the support device to occupy the spaces, or apertures, between the spring fingers of the EMI shield. For example, the spacing between spring fingers of the EMI shield may be sufficient for attenuation of lower frequencies of EMI generated by drives or other components for which the EMI shield was originally designed. The EMI shield may therefore have a larger aperture size/characteristic length between spring fingers to allow increased airflow. However, in addition to not exhibiting a sufficient spring tension when used in a larger sized slot/bay, the EMI shield may also fail to attenuate higher frequency EMI due to a relatively wider spacing between the fingers of the EMI shield. By occupying the spaces, or at least portions of the spaces between spring fingers of the EMI shield with the metallic tabs of the support device, attenuation of higher frequency EMI may be provided. In general, the higher frequency of radiation to be attenuated, the smaller aperture that should be provided. Although there may be a decrease in airflow due to the aperture size reduction, the support device of the present disclosure also allows the use of wider slots/bays, which may provide for increased airflow around the sides of the drives from a front to a rear of the chassis.

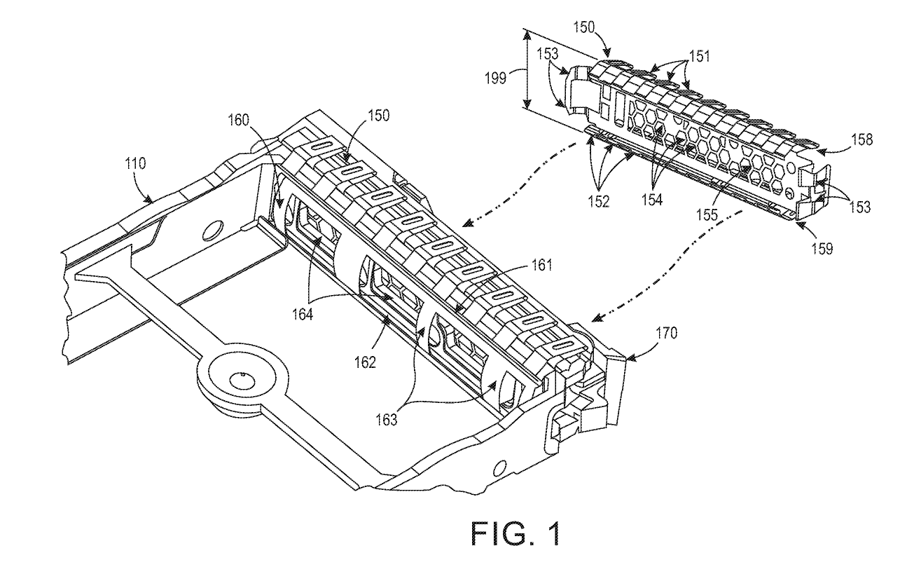

Accordingly, the present disclosure provides for an add-on support device to provide a stiffer set of EMI shield spring fingers that increases spring tension and provides greater electrical grounding capability for higher data speeds. This also allows the slot pitch or spacing of drive carriers within the chassis to be increased, which accommodates increased air flow and improved cooling. In one example, the apertures or gaps between EMI shield spring fingers are also reduced, thereby providing emission shielding for higher data speeds (and thus higher frequency EMI). As such, an existing drive carrier can be retro-fitted into a drive cage with increased slot/bay sizes, while controlling and accommodating the higher frequencies and data speeds of new/upgraded electronics. These and other aspects of the present disclosure are discussed in greater detail below in connection with the example FIGS. 1-3.

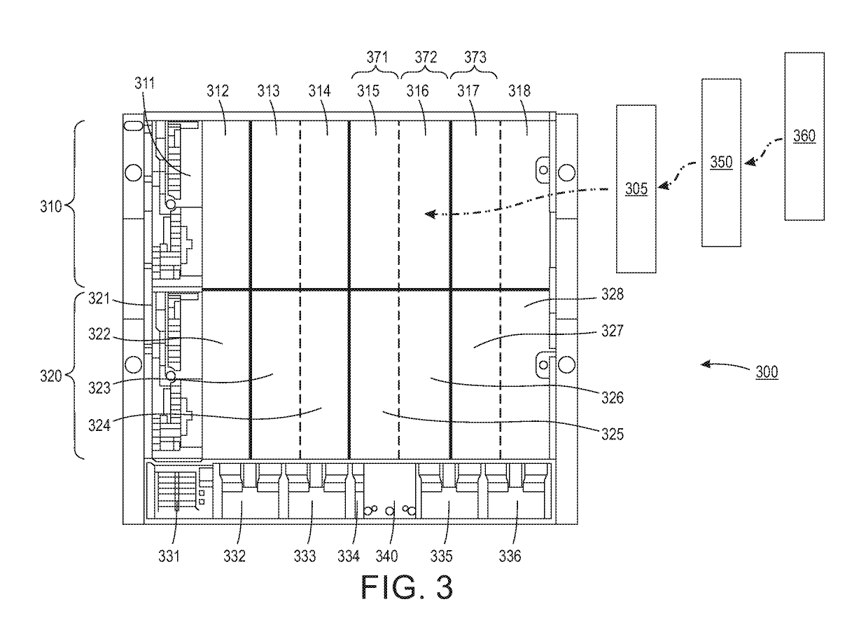

Referring now to FIG. 1, a portion of an example drive carrier 100 is illustrated. Drive carrier 100 may include a housing 110, a bezel 170, and an EMI shield 150. The housing 110 may fit within a slot/bay of a chassis. An example chassis or drive enclosure is illustrated in FIG. 3 and described in greater detail below. The EMI shield 150 is illustrated both integral with the housing 110 (at the bezel end) and separate from the housing 110 in order to show additional details. For instance, EMI shield 150 may include two rows of spaced apart spring fingers, the first row 158 including spring fingers 151 and the second row 159 including spring fingers 152. The two rows may extend parallel to a length (the longest dimension) of the bezel 170. However, the spring fingers 151 and 152 may be oriented in parallel to one another and perpendicular to a length of the bezel 170. For ease of illustration, only some of the spring fingers 151 in the first row 158 and spring fingers 152 in the second row 159 are labeled.

The EMI shield 150 may also include spring fingers 153 on two sides of the EMI shield 150. Thus, spring fingers 151, 152, and 153 may extend out from a perimeter of a front panel 155 of the EMI shield 150. In one example, the EMI shield 150 is constructed of a single piece of conductive material, e.g., a conductive metal. The spring fingers 151, 152, and 153 may maintain contact with a drive cage/chassis, such as a chassis wall, and/or components of an adjacent drive carrier in the chassis, such as spring fingers of one or more EMI shields or other components of one or more other drive carriers in adjacent chassis slots. In one example, each of the spring fingers 151, 152, and 153 may comprise a sheet spring, e.g., a sheet metal spring. In one example, each of the spring fingers 151, 152 and 153 may comprise a steel leaf spring.

EMI shield 150 may further include air inlet holes 154 in the front panel 155. Cooling inlet air from one or more fans (not shown) may flow through openings in the bezel 170, through the air inlet holes 154, and through apertures or gaps between the spring fingers 151 and 152. It should be noted that EMI shield 150 is illustrated in one example representation in FIG. 1, and that EMI shield 150 may take a variety of other forms. For instance, air inlet holes 154 are illustrated in a honeycomb pattern. However, in another example, front panel 155 may include air inlet holes in a different pattern, such as square or rectangular openings, circular or oval openings, and so forth.

Drive carrier 100 may further include a support device 160 to support the EMI shield 150. In one example, the support device 160 may be formed from a single piece of conductive material. For instance, the support device 160 may be fabricated from a same material as the EMI shield 150, e.g., a conductive metal. In another example, the support device 160 may comprise a different material, such as a plastic, carbon fiber, or other rigid material. The support device 160 may include a first bar 161 that extends parallel to a length of the bezel 170 and a second bar 162 parallel to the first bar 161. The support device 160 may further include a plurality of support ribs 163 perpendicular to and between the first bar 161 and the second bar 162, with a plurality of airflow openings 164. Cooling inlet air from one or more fans (not shown) may flow through openings in the bezel 170, through the air inlet holes 154 of the front panel 155 of the EMI shield 150, and through the airflow openings 164. As illustrated in FIG. 1, support device 160 includes five support ribs 163, with four airflow openings 164. However, in other, further, and different examples, more or less support ribs 163 and airflow openings 164 may be provided.

The support ribs 163 may maintain the first bar 161 in contact with the spring fingers 151 and to maintain the second bar 162 in contact with the spring fingers 152, and to maintain a spring tension in the spring fingers 151 and 152. For example, when not installed in a slot/bay of a chassis and not compressed by spring fingers of adjacent drive carriers or chassis walls, the first bar 161 and the second bar 162 may support the spring fingers 151 and 152 of the EMI shield 150 in an extended position as compared to a resting position of the spring fingers 151 and 152. In other words, a separation distance 199 between spring fingers 151 of the first row 158 and spring fingers 152 of the second row 159 is greater when the support device 160 is between the first row 158 and the second row 159 as compared to when the support device 160 is not between the first row 158 and the second row 159.

To maximize airflow, the number of support ribs 163 and the widths, thicknesses, and other dimensions of the support ribs 163 may be configured for the support device 160 to have as large of airflow openings 164 as can fit within the space available between the first bar 161 and the second bar 162, while at the same time having sufficient rigidity to extend, or spread the spring fingers 151 and 152 without fatiguing to support device 160. Thus, the EMI shield 150 and support device 160 may collectively comprise an EMI system that can be used to deploy the drive carrier 100 in a larger bay/slot than would otherwise be possible with the EMI shield 150 alone. For example, a slot pitch of the chassis for the drive carrier 100 may be greater than the separation distance 199 between the first row 158 and the second row 159 when the support device 160 is not situated between the first row 158 and the second row 159. In contrast, the first row 158 and the second row 159 of the EMI shield 160 may span the slot pitch when the support device 160 is situated between the first row 158 and the second row 159.

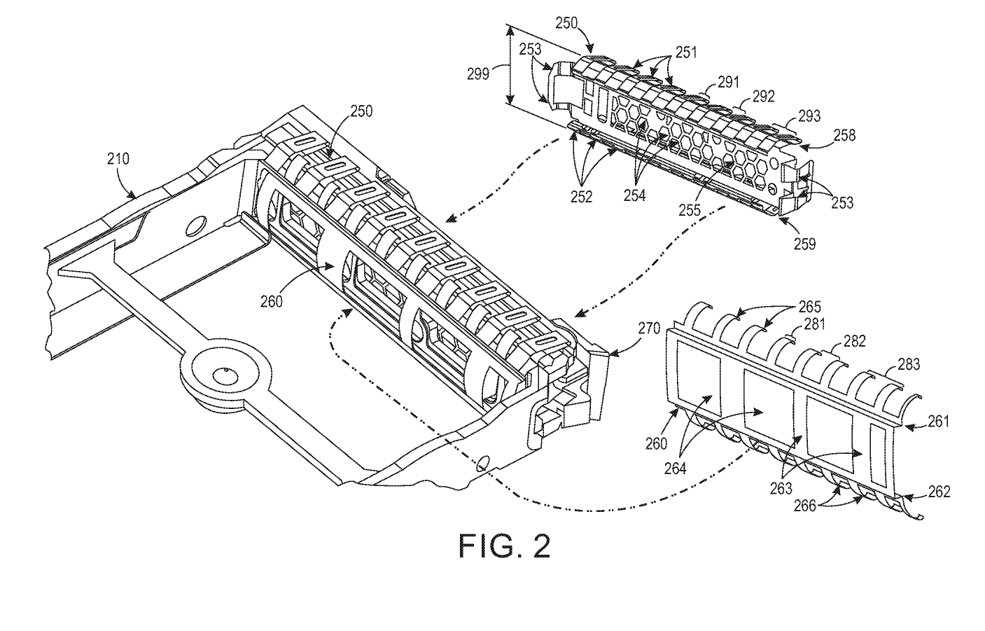

FIG. 2 illustrates an additional isometric view of a portion of an example drive carrier carrier 200, including an example EMI shield 250 and an example support device 260. As illustrated, in FIG. 2, drive carrier 200 may further comprise a housing 210 and a bezel 270. The housing 210 may fit within a slot/bay of a chassis. An example chassis or drive enclosure is illustrated in FIG. 3 and described in greater detail below. The EMI shield 250 and the support device 260 are illustrated both integral with the housing 210 (at the bezel end) and separate from the housing 210 in order to show additional details. For instance, EMI shield 250 may include two rows of spaced apart spring fingers, the first row 258 including spring fingers 251 and the second row 259 including spring fingers 252. The two rows may extend parallel to a length (the longest dimension) of the bezel 270. However, the spring fingers 251 and 252 may be oriented in parallel to one another and perpendicular to a length of the bezel 270. For ease of illustration, only some of the spring fingers 251 in the first row 258 and spring fingers 252 in the second row 259 are labeled.

The EMI shield 250 may also include spring fingers 253 on two sides of the EMI shield 250. Thus, spring fingers 251, 252, and 253 may extend out from a perimeter of a front panel 255 of the EMI shield 250. In one example, the EMI shield 250 is constructed of a single piece of conductive material, e.g., a conductive metal. The spring fingers 251, 252, and 253 may maintain contact with a drive cage/chassis, such as a chassis wall, and/or components of an adjacent drive carrier in the chassis, such as spring fingers of one or more EMI shields or other components of one or more other drive carriers in adjacent chassis slots. In one example, each of the spring fingers 251, 252, and 253 may comprise a sheet spring, e.g., a sheet metal spring. In one example, each of the spring fingers 251, 252 and 253 may comprise a steel leaf spring. EMI shield 250 may further include air inlet holes 254 in the front panel 255. Cooling inlet air from one or more fans (not shown) may flow through openings in the bezel 270, through the air inlet holes 254, and through apertures or gaps between the spring fingers 251 and 252, e.g., aperture 292. It should be noted that EMI shield 250 is illustrated in one example representation in FIG. 2, and that EMI shield 250 may take a variety of other forms. In one example, the housing 210, bezel 270, and EMI shield 250 may comprise the same or a substantially similar components to the housing 110, bezel 170, and EMI shield 150 of FIG. 1.

Drive carrier 200 may further include a support device 260 to support the EMI shield 250. In one example, the support device 260 may be formed from a single piece of conductive material. For instance, the support device 260 may be fabricated from a same material as the EMI shield 250, e.g., a conductive metal. In another example, the support device 260 may comprise a different material, such as a plastic, carbon fiber, or other rigid material. The support device 260 may include a first bar 261 that extends parallel to a length of the bezel 270 and a second bar 262 parallel to the first bar 261. The support device 260 may further include a plurality of support ribs 263 perpendicular to and between the first bar 261 and the second bar 262, with a plurality of airflow openings 264. Cooling inlet air from one or more fans (not shown) may flow through openings in the bezel 270, through the air inlet holes 254 of the front panel 255 of the EMI shield 250, and through the airflow openings 264.

The first bar 261, second bar 262, and support ribs 263 may comprise the same or a substantially similar components to the first bar 161, second bar 162, and support ribs 163 of the support device 160 of FIG. 1. For example, the support ribs 263 may maintain the first bar 261 in contact with the spring fingers 251 and maintain the second bar 262 in contact with the spring fingers 252, and maintain a spring tension in the spring fingers 251 and 252. For example, when not installed in a slot/bay of a chassis and not compressed by spring fingers of adjacent drive carriers or chassis walls, the first bar 261 and the second bar 262 may support the spring fingers 251 and 252 of the EMI shield 250 in an extended position as compared to a resting position of the spring fingers 251 and 252. In other words, a separation distance 299 between spring fingers 251 of the first row 258 and spring fingers 252 of the second row 259 is greater when the support device 260 is between the first row 258 and the second row 259 as compared to when the support device 260 is not between the first row 258 and the second row 259. To maximize airflow, the number of support ribs 263 and the widths and other dimensions of the support ribs 263 may be configured in the same or in a similar manner as described above in connection with the support device 160 of FIG. 1.

Thus, the EMI shield 250 and support device 260 may collectively comprise an EMI system that can be used to deploy the drive carrier 200 in a larger bay/slot than would otherwise be possible with the EMI shield 250 alone. For example, a slot pitch of the chassis for the drive carrier 200 may be greater than the separation distance 299 between the first row 258 and the second row 259 when the support device 260 is not situated between the first row 258 and the second row 259. However, the first row 258 and the second row 259 of the EMI shield 260 may span the slot pitch when the support device 260 is situated between the first row 258 and the second row 259.

In addition to stiffening the spring fingers 251 and 252 of the EMI shield 260, the support device 260 may also provide for attenuation of additional high frequency EMI as compared to the attenuation capabilities of the EMI shield 250 alone. For example, the widths, gaps, and/or spacings of spring fingers 251 and 252 of the EMI shield 250 may be sufficient for attenuation of lower frequencies of EMI generated by drives or other components for which the EMI shield 250 was originally designed. A representative spring finger width 291, a representative spring finger gap 292, and a representative spring finger spacing 293 (e.g., a center-to-center distance between spring fingers) are illustrated in FIG. 2. The EMI shield 250 may therefore have relatively larger apertures between spring fingers to allow increased airflow. However, in addition to lacking sufficient spring tension when used in a larger sized slot/bay (e.g., without the use of the example support device 260), the EMI shield 250 may also fail to attenuate higher frequency EMI due to the relatively larger apertures between the spring fingers 251 and 252 of the EMI shield 250.

In one example, the attenuation of high frequency EMI may be provided by a plurality of tabs 265 and 266 extending perpendicular to the first bar 261 and second bar 262 of the support device 260 to occupy the spaces between spring fingers 251 and 252, such as indicated by the example aperture or gap 292. For ease of illustration only some of the tabs 265 and 266 are specifically labeled in FIG. 2. In one example, widths, gaps, and/or spacings of tabs 265 and 266 may correspond to the characteristics of the spring fingers 251 and 252 of the EMI shield 250, such as the widths, gaps, and/or spacings of the spring fingers 251 and 252. A representative tab width 281, a representative tab gap 282, and a representative tan spacing 283 (e.g., a center-to-center distance between tabs) are illustrated in FIG. 2. In one example, the tabs 265 and 266 may fill or substantially fill the apertures between the spring fingers 251 and 252. In one example, the tabs 265 and 266 may at least reduce an aperture size between spring fingers 251 and 252. In one example, the tabs 255 and 256 may be integrally formed as a single piece with other components of support device 260. In one example, the tabs may comprise a conductive material, which may be a same or a different material as the EMI shield 260. In one example, the tabs 255 and 256 may also comprise springs to maintain contact with a chassis for the drive carrier 200 or to maintain contact with components of an adjacent drive carrier in the chassis. For example, the tabs 255 and 256 may connect with tabs of another support device of an adjacent drive carrier when installed in a slot of a chassis, may connect with spring fingers or another portion of an EMI shield of a drive carrier in an adjacent slot, and so forth. As such, the example support device 260 of FIG. 2 provides both spring stiffening for improved EMI grounding and reduced aperture/gap size between spring fingers for containment of higher frequency radiation. In addition, it should be noted that various components of drive carrier 100 and drive carrier 200 are omitted from FIGS. 1 and 2 for illustrative purposes. For example, the drives installed in the respective drive carriers, mounting screws, and so forth are omitted from FIGS. 1 and 2.

FIG. 3 illustrates a front view of an example drive carrier chassis 300, including at least one drive carrier 305 with an example EMI shield 350 and an example support device 360. The drive carrier 305 may comprise a same or a similar component as drive carrier 100 of FIG. 1 or drive carrier 200 of FIG. 2. Similarly, EMI shield 350 and support device 360 may comprise the same or similar components to EMI shield 150 and support device 160 of FIG. 1, or EMI shield 250 and support device 260 of FIG. 2, respectively. As illustrated in the example of FIG. 3, drive carrier 305 may be deployed in a slot 316 of the chassis 300. In the present example, chassis 300 may include a first row 310 comprised of slots 311-318 and a second row 320 comprised of slots 321-328. Chassis 300 may further include power supply bays 331-336 and a display 340. In one example, chassis 300 may comprise a blade enclosure.

As mentioned above, the slot pitch (e.g., the spacing between bays and/or the width of each bay) may be increased from standard slot/bay sizes. This may provide improved cooling of the drives in the chassis 300 through increased airflow around the sides of the drives from a front to a rear of the chassis 300. For instance, drives, drive carriers, and EMI shields may be sized for use in 2.5 inch bays, 3.5 inch bays, or 5.25 inch bays (where, the inch size is in reference to the historical disk size used in the bay, and is not necessarily representative of the actual bay cross-sectional dimensions). The slot pitch, or bay size, may therefore be increased with respect to the customary dimensions. For example, drive carrier 305 and EMI shield 350 may be designed and optimized for a 3.5 inch slot/bay, while the slot widths 371, 372, and 373 of slots 315, 316, and 317, respectively may be increased from the 3.5 inch slot/bay size. Spring fingers of EMI shield 350 may therefore fail to maintain sufficient contact force and/or fail to connect to spring fingers of EMI shields or other components of drive carriers installed in slots 315 and 317 when the drive carrier 305 is deployed in slot 316. In one example, a slot pitch of the chassis 300 may be greater than a separation distance between a first row of spring fingers and a second row of spring fingers of the EMI shield 350. However, when support device 360 is used to increase the stiffness of the spring fingers of the EMI shield 350, the EMI shield 350 may span the slot pitch in slot 316 and make adequate contact with other components, such as spring fingers of EMI shields, in the adjacent slots 315 and 317.

It should be noted that additional support devices may be utilized in connection with EMI shields in any one or more of the slots 311-318 in row 310 and slots 321-328 in row 320. In this regard, support device 360 may include a plurality of tabs which may also make contact with corresponding tabs of support devices in slots 315 and 317, for example. It should also be noted that the example of FIG. 3 has been simplified. For example, details of each drive carrier, drive and/or blade may be omitted from each of the slots. Similarly, details of the drive carrier 305, EMI shield 350, and support device 360 are not shown in FIG. 3. In addition, fans, power supply cables, and other components are omitted for illustrative purposes.

It will be appreciated that variants of the above-disclosed and other features and functions, or alternatives thereof, may be combined into many other different systems or applications. Various presently unforeseen or unanticipated alternatives, modifications, or variations therein may be subsequently made, which are also intended to be encompassed by the following claims.

What is claimed is:

1. A support device for an electromagnetic interference shield of a drive carrier, the support device comprising:
a first bar to extend parallel to a length of a bezel of the drive carrier;
a second bar parallel to the first bar, the first bar and the second bar to support spring fingers of the electromagnetic interference shield, the spring fingers comprised of a conductive material, the spring fingers oriented in parallel to one another and perpendicular to the length of the bezel of the drive carrier; and
a plurality of support ribs perpendicular to and between the first bar and the second bar, the plurality of support ribs to maintain the first bar and the second bar in contact with the spring fingers and to maintain a spring tension in the spring fingers.

2. The support device of claim 1, wherein the spring fingers comprise a first row of spring fingers and a second row of spring fingers, the plurality of support ribs to maintain the first bar in contact with the first row of spring fingers and to maintain the second bar in contact with the second row of spring fingers.

3. The support device of claim 1, further comprising:
a plurality of tabs to occupy spaces between the spring fingers of the electromagnetic interference shield.

4. The support device of claim 3, wherein the plurality of tabs comprises springs to maintain contact with a chassis for the drive carrier or to maintain contact with components of an adjacent drive carrier in the chassis.

5. The support device of claim 1, further comprising:
a plurality of airflow openings between the plurality of support ribs, the first bar, and the second bar.

6. An electromagnetic interference system for a drive carrier, the electromagnetic interference system comprising:
an electromagnetic interference shield comprising:
a panel; and
spring fingers attached to the panel, the spring fingers comprised of a conductive material, the spring fingers oriented in parallel to one another and perpendicular to a length of a bezel of the drive carrier; and
a support device comprising:
a first bar to extend parallel to the length of the bezel of the drive carrier;
a second bar parallel to the first bar, the first bar and the second bar to support the spring fingers of the electromagnetic interference shield; and
a plurality of support ribs perpendicular to and between the first bar and the second bar, the plurality of support ribs to maintain the first bar and the second bar in contact with the spring fingers and to maintain a spring tension in the spring fingers.

7. The electromagnetic interference system of claim 6, wherein the spring fingers of the electromagnetic interference shield are to maintain contact with a chassis for the drive carrier or to maintain contact with components of an adjacent drive carrier in the chassis.

8. The electromagnetic interference system of claim 6, wherein the spring fingers comprise a first row of spring fingers and a second row of spring fingers, the plurality of support ribs to maintain the first bar in contact with the first row of spring fingers and to maintain the second bar in contact with the second row of spring fingers.

9. The electromagnetic interference system of claim 8, wherein a separation distance between the first row of spring fingers and the second row of spring fingers is greater when the support device is between the first row and the second row as compared to when the support device is not between the first row and the second row.

10. The electromagnetic interference system of claim 8, wherein the support device further comprises:
a plurality of tabs to occupy spaces between the spring fingers of the electromagnetic interference shield.

11. The electromagnetic interference system of claim 10, wherein the plurality of tabs comprises springs to maintain contact with a chassis for the drive carrier or to maintain contact with components of an adjacent drive carrier in the chassis.

12. A drive carrier for a chassis, the drive carrier comprising:
a housing to fit in a slot of the chassis;
an electromagnetic interference shield comprising a plurality of spring fingers, the electromagnetic interference shield affixed to the housing; and
a support device comprising:
a first bar to extend parallel to a length of a bezel of the drive carrier;
a second bar parallel to the first bar, the first bar and the second bar to support the plurality of spring fingers of the electromagnetic interference shield; and
a plurality of support ribs perpendicular to and between the first bar and the second bar, the plurality of support ribs to maintain the first bar and the second bar in contact with the plurality of spring fingers and to maintain a spring tension in the spring fingers.

13. The drive carrier of claim 12, wherein the spring fingers of the electromagnetic interference shield are to maintain contact with the chassis or to maintain contact with components of an adjacent drive carrier in the chassis.

14. The drive carrier of claim 12, wherein a slot pitch of the chassis for the drive carrier is greater than a separation distance between a first row of spring fingers of the plurality of spring fingers of the electromagnetic interference shield and a second row of spring fingers of the plurality of spring fingers of the electromagnetic interference shield that is parallel to the first row, when the support device is not situated between the first row and the second row.

15. The drive carrier of claim 14, wherein the electromagnetic interference shield spans the slot pitch when the support device is situated between the first row and the second row.
